(19) United States
(12) Patent Application Publication
(10) Pub. No.: US 2009/0039462 A1
(43) Pub. Date: Feb. 12, 2009

(54) EFUSE DEVICES AND EFUSE ARRAYS THEREOF AND EFUSE BLOWING METHODS

(75) Inventor: Rei-Fu Huang, Tainan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/128,650

(22) Filed: May 29, 2008

Related U.S. Application Data
(60) Provisional application No. 60/954,337, filed on Aug. 7, 2007.

(51) Int. Cl. H01H 37/76; H01L 21/00

(52) U.S. Cl. 257/529; 327/525; 257/E21.001

(57) ABSTRACT

An exemplary embodiment of an efuse device is provided and comprises a plurality of word lines, at least one bit line, a plurality of cells, a plurality of first selection devices, and at least one second selection device. The word lines are interlaced with the bit line. The cells are disposed in an array, and each corresponds to one set of the interlaced word line and bit line. Each first selection device is coupled to one of the word lines, and the second selection device is coupled to the bit line.

### CROSS REFERENCE TO RELATED APPLICATIONS

The present application claims the benefit of U.S. provisional application entitled “HIGH DENSITY EFUSE ARRAY AND SENSE AMP DESIGN”, Ser. No. 60/954,337, filed Aug. 7, 2007.

### BACKGROUND OF THE INVENTION

1. Field of the Invention

The invention relates to an efuse device, and more particularly to an efuse array with two-domain decoding.

2. Description of the Related Art

FIG. 1 shows a conventional efuse array. Referring to FIG. 1, a 4×2 efuse array 10 is given as an example. The efuse array 10 comprises cells (referring to fuses 100-107) and blowing transistors T100-T107. Each of blowing transistors T100-T107 is coupled between one cell and a reference voltage. When one cell is determined to be blown in a writing mode, the corresponding blowing transistor is turned on, and a blowing current on a source line SL is provided to the determined cell through the turned-on blowing transistor to blow it. For example, in the writing mode, if the cell 100 is determined to be blown, the blowing transistor T100 is turned on, and the blowing current on the source line SL is provided to the cell 100 through the turned-on blowing transistor T100, so that the cell 100 is blown (or programmed).

However, the blowing transistors T100-T107 have large size. Moreover, according to the blowing method of the efuse array 10, each of the cells requires one sensing circuit for outputting signal in a reading mode. Thus, the efuse array 10 occupies a large area.

### BRIEF SUMMARY OF THE INVENTION

An exemplary embodiment of an efuse device comprises a plurality of word lines, at least one bit line, a plurality of cells, a plurality of first selection devices, and at least one second selection device. The word lines are interlaced with the bit line. The cells are disposed in an array, and each corresponds to one set of the interlaced word line and bit line. Each first selection device is coupled to one of the word lines, and the second selection device is coupled to the bit line.

An exemplary embodiment of an efuse device comprises a plurality of first lines, at least one second line, a plurality of cells, a plurality of first selection devices, at least one second selection device, and a plurality of sensing circuits. The first lines are interlaced with the second line. The cells are disposed in an array. Each cell corresponds to one set of the interlaced first line and second line and has first and second terminals respectively coupled to the corresponding interlaced first line and second line. Each first selection device is coupled to one of the first lines, and the second selection device is coupled to the second line. Each sensing circuit is coupled to the second line and one of the first lines. The states of the cells coupled to the same first line are sensed by the same sensing circuit.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional efuse array.

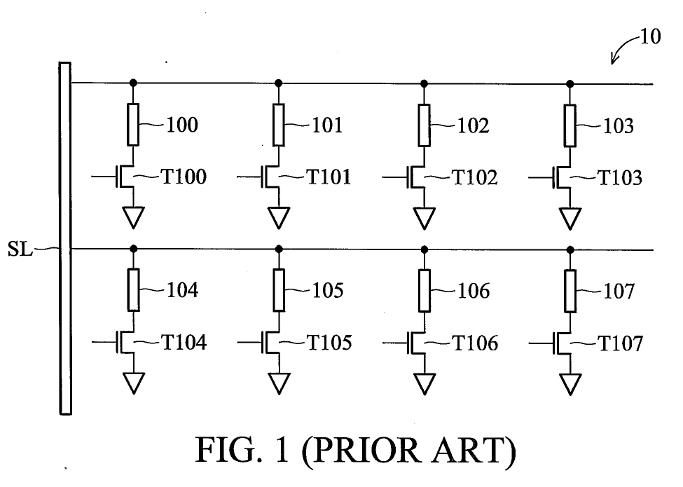

FIG. 2 shows an exemplary embodiment of an efuse device;

FIG. 3 shows an exemplary embodiment of a cell and a sensing circuit; and

FIG. 4 shows waveforms of signals of the efuse device in the reading mode.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

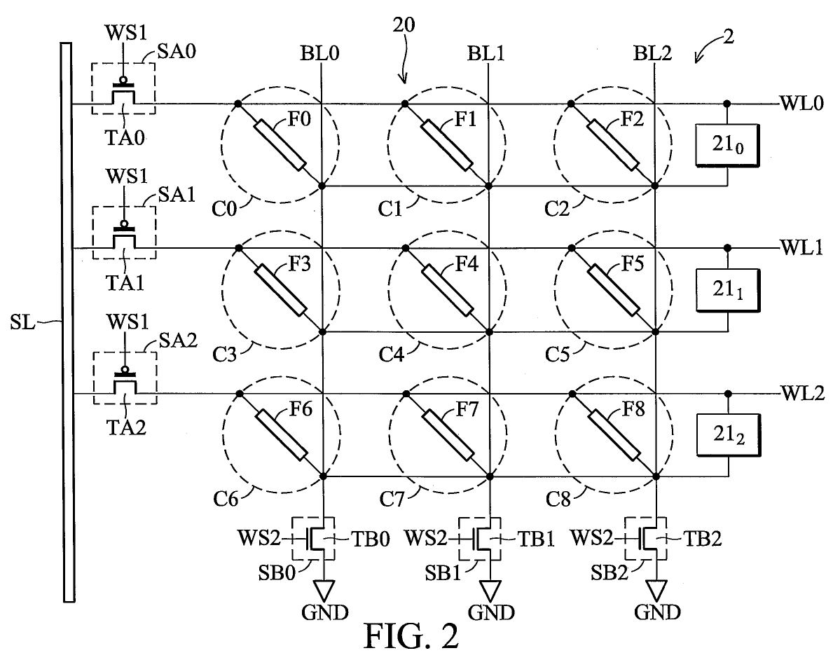

In an exemplary embodiment of an efuse device in FIG. 2, an efuse device 2 comprises an efuse array 20 and sensing circuits 21. In this embodiment, the efuse array 20 is given as an example to be a 3×3 efuse array. The efuse array 20 comprises a plurality of word lines WL0-WL2, a plurality of bit lines BL0-BL2, a plurality of selection devices SA0-SA2 and SB0-SB2, and a plurality of cells C0-C8. Referring to FIG. 2, the word lines WL0-WL2 are disposed sequentially, wherein each word line may be along the horizontal direction. The bit lines BL0-BL2 are disposed sequentially, wherein each bit line may be along the vertical direction. Thus, the word lines WL0-WL2 are interlaced with the bit lines BL0-BL2. The cells C0-C8 are disposed in an array, and each cell corresponds to one set of the interlaced word line and bit line. For example, the cell C0 corresponds to the set of the interlaced word line WL0 and the bit line BL0, in other words, one terminal of the cell C0 is coupled to the word line WL0, and the other terminal thereof is coupled to the bit line BL0. The cells C0-C8 comprise fuses F0-F8, respectively. Thus, each fuse is coupled between the corresponding interlaced word and bit lines.

The selection devices SA0-SA2 are coupled to the word lines WL0-WL2 respectively, and the selection devices SB0-SB2 are coupled to the bit lines BL0-BL2, respectively. In this embodiment, the selection devices coupled to the word lines WL0-WL2 comprise the same type of transistors, and the selection devices coupled to the bit lines BL0-BL2 comprises the same type of transistors. The selection devices SA0-SA2 may comprise PMOS or NMOS transistors TA0-TA2, and the transistors TA0-TA2 of the selection devices SA0-SA2 may have thick or thin gate oxide layers. The selection devices SB0-SB2 may comprise NMOS transistors TB0-TB2. Referring to FIG. 2, in this embodiment, thick-gate PMOS transistors TA0-TA2 in the selection devices SA0-SA2 are given as an example. Each of the PMOS transistor TA0-TA2 has a control terminal (gate) receiving a writing signal WS1, a first terminal (source) coupled to a source line SL, and a second terminal (drain) coupled to the corresponding word line. Each of the transistors TB0-TB2 has a control terminal (gate) receiving a writing signal WS2, a first terminal (source) coupled to a ground voltage GND, and a second terminal coupled to the corresponding bit line.

Referring to FIG. 2, each of the sensing circuits 210-212 is coupled to one of the word lines WL0-WL2 and all of the bit lines BL0-BL2, and the sensing circuits 210-212 are arranged to sense states of the cells C0-C8, such as if the cells are blown or not. For example, the sensing circuit 211 is coupled to the word line WL0 and the bit lines BL0-BL2, and the states of cells C0-C2 on the word line WL0 are sensed by the sensing circuit 210. In some embodiments, each of the sensing circuits 210-212 is coupled to one of the bit lines BL0-BL2 and all of the word lines WL0-WL2, and the states of the cells coupled to the same bit line are sensed by the same sensing circuit.

The efuse device 2 may operate in a writing mode and a reading mode. In the writing mode, at least one of the fuses F0-F8 is determined to be blown or programmed. In the following description, it is assumed that the fuses F1 and F4 are determined to be blown, wherein the fuse F1 corresponds to the interlaced word line WL0 and the bit line BL1, and the fuse F4 corresponds to the interlaced word line WL1 and bit line BL1. In the writing mode, the transistors TA0 and TA1 respectively coupled to the word lines WL0 and WL1 are turned on by the writing signal WS1, and the transistor TB1 coupled to the bit line BL1 is turned on by the writing signal WS2 for addressing the location of the fuses F1 and F4. At this time, a current is provided by the source line SL to the fuses F1 and F4 respectively through the word lines WL0 and WL1, so that the fuses F1 and F4 are selected to be blown (or programmed).

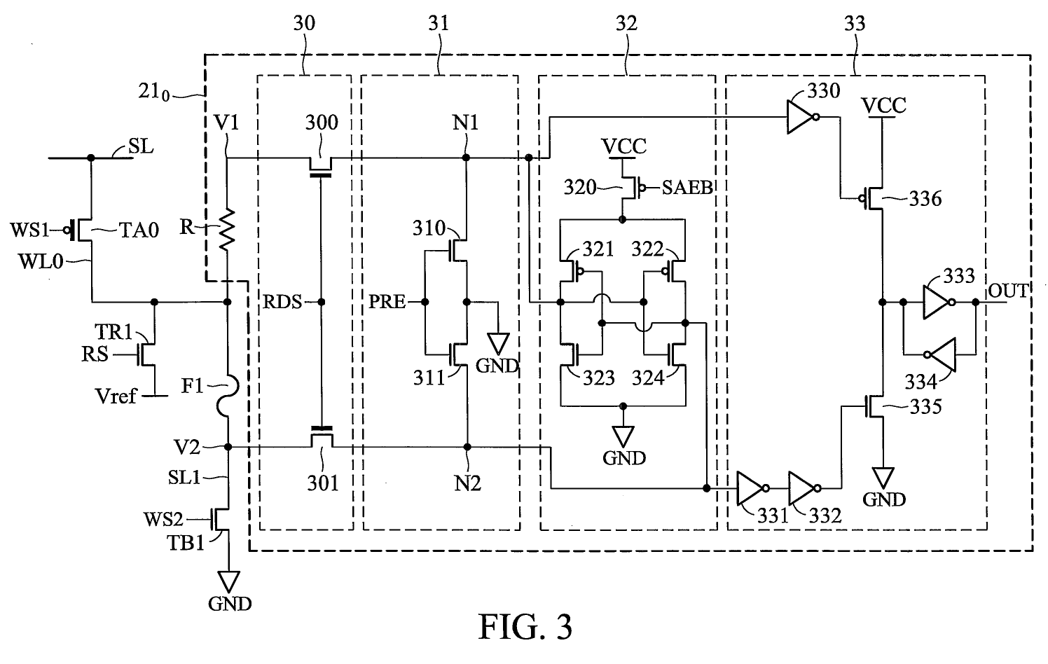

The operation of the efuse device 2 in the reading mode is described according to FIG. 3. For a clear description, the fuse F1 and the sensing circuit 21₀ both coupled to the word line WL0 are given as an example. The sensing circuits 21₁-21₂ may have similar structures to the sensing circuit 21₀ of FIG. 3. The sensing circuit 21₀ may comprise a reference resistor R, an isolation unit 30, a pre-charging unit 31, an amplifying unit 32, and an output unit 33. Furthermore, the efuse device 2 further comprises a plurality of reading transistors, and each of the reading transistors is coupled between one fuse and a reference voltage Vref, wherein in this embodiment, the reference voltage Vref has a high level. Referring to FIG. 3, only reading transistor TR1 coupled between the corresponding fuse F1 and the reference voltage Vref is shown. The reference resistor R has a first terminal coupled to the fuses F0-F2 on the word line WL0 and a second terminal coupled to the isolation unit 30, wherein FIG. 3 only shows the fuse F1. The isolation unit 30 is coupled between the second terminal of the reference resistor R and the bit line BL1 and comprises two NMOS transistors 300 and 301 controlled by a reading-enable signal RDS. The isolation unit 30 is turned off in the writing mode and on in the reading mode. The pre-charging unit 31 is coupled to the isolation unit 30 through input nodes N1 and N2 and comprises two NMOS transistors 310 and 311 controlled by a pre-charge signal PRE. The NMOS transistors 310 and 311 are coupled together at the ground voltage GND. The amplifying unit 32 is coupled to the input nodes N1 and N2 of the pre-charging unit 31 and comprises PMOS transistors 320-322 and NMOS transistors 323-324, wherein the PMOS transistor 320 is controlled by a sensing signal SAEB. The PMOS transistors 321-322 and NMOS transistors 323-324 compose two inverters in an inverse connection. The output unit 33 is coupled to the amplifying unit 32 and comprises inverters 330-334, an NMOS transistor 335, and a PMOS transistor 336.

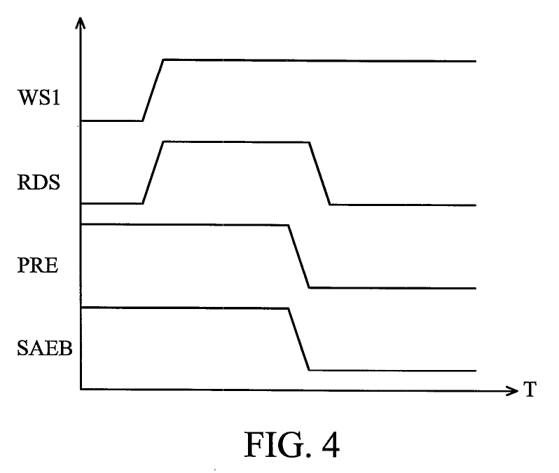

FIG. 4 shows waveforms of signals of the efuse device 2 in the reading mode. It is assumed the fuse F1 is desired to be read. Referring to FIGS. 3 and 4, in the reading mode, before the isolation unit 30 is turned on, the NMOS transistors 310 and 311 of the pre-charge unit 31 are turned on by the pre-charge signal PRE with a high level, so that voltages at the input nodes N1 and N2 of the pre-charge unit 31 are charged to a predetermined level. In this embodiment, the predetermined level is a low level. Then, the writing signal WS1 becomes high to turn off the transistor TA0, and the transistor TB1 is turned off by the writing signal WS2. The reading transistor TR1 is turned on by a reading signal RS. At this time, a voltage V1 of the second terminal of the reference resistor R and a voltage V2 on the bit line BL1 respectively refer to impedance of the reference resistor R and impedance of the fuse F1. In detail, a ratio of the voltage V1 to the voltage V2 is proportional to a ratio of impedance of the reference resistor R to that of the fuse F1. The impedance of the fuse F1 is greater when the fuse F1 is blown than when it is not blown. The transistors 300 and 301 of the isolation unit 30 are turned on by the reading-enable signal RDS with a high level. The input nodes N1 and N2 of the pre-charging unit 31 respectively receive the voltage V1 and the voltage V2 through the turned-on isolation unit 30. At this time, the voltages at the input nodes N1 and N2 are equal to the voltages V1 and V2 respectively.

Then, the transistors 300 and 301 of the isolation unit 30 are turned off by the reading-enable signal RDS with a low level, and the NMOS transistors 310 and 311 of the pre-charge unit 31 are turned off by the pre-charge signal PRE with a low level. The PMOS transistor 320 is turned on by the sensing signal SAEB with a low level. The amplifying unit 32 begins to amplify the voltages V1 and V2 at the input nodes N1 and N2 to a sufficiently high level. The output unit 33 receives the amplified voltages V1 and V2 and outputs an output signal OUT according to the amplified voltages V1 and V2. The output signal OUT represents the state of the fuse F1. For example, the output signal OUT with logic “1” represent the fuse F1 is blown. If the fuse F1 is not blown by current, the output signal OUT has a logic “0”.

In FIGS. 3 and 4, the structure of the sensing circuit 210, the circuitry of units 30-33, and the timing of the signals RDS, PRE, SAEB are given as an example, but not limitation. In different applications, the sensing circuits can have different structures and different signal timing according to requirements.

In this embodiment, before the isolation unit 30 is turned on, the pre-charge unit 31 pre-charges the voltages at the input nodes N1 and N2 to a low level. In other embodiments, if the pre-charge unit 31 is desired to charge the voltages at the input nodes N1 and N2 to a high level, the reference voltage Vref has a low level, the NMOS transistors 310 and 311 are replaced by two PMOS transistors whose gates receives a signal inverse to the pre-charge signal PRE, and the PMOS transistors are coupled together at a voltage source VCC.

According to above embodiment, each word line has one selection device, and each bit line has one selection device, so that the fuses can be selected for blowing by two-domain decoding in the writing mode. Besides, it is not necessary to change the voltage supplied to the source line SL when change between writing and reading modes. Moreover, the cells on the same word line or on the same bit line share a sensing circuit. Thus, the area of the efuse device 2 can be decreased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An efuse array comprising:
a plurality of word lines;
at least one bit line, where the word lines are interlaced with the bit line;
a plurality of cells disposed in an array, each corresponding to one set of the interlaced word line and bit line;
a plurality of first selection devices, each coupled to one of the word lines; and
at least one second selection device, coupled to the bit line.

2. The efuse array as claimed in claim 1, wherein in a writing mode, when at least one first selection device and the second selection device are turned on, at least one cell, which corresponds to the interlaced word and bit lines of the turned-on first and second selection devices, is selected.

3. The efuse array as claimed in claim 1, wherein each first selection device comprises a first transistor having a control terminal receiving a first writing signal, a first terminal coupled to a source line, and a second terminal coupled to the corresponding word line, and the second selection device comprises a second transistor having a control terminal receiving a second writing signal, a first terminal coupled to a ground voltage, and a second terminal coupled to the bit line.

4. The efuse array as claimed in claim 3, wherein in a writing mode, when at least one first transistor and the second transistor are turned on respectively by the first and second writing signals, at least one cell, which corresponds to the interlaced word and bit lines of the turned-on first and second transistors, is selected.

5. The efuse array as claimed in claim 3, wherein each of the cells comprises a fuse, and the source line provides a current for blowing the fuses.

6. The efuse array as claimed in claim 3, wherein the first transistors are P-type MOS transistors, and the second transistor is an N-type MOS transistor.

7. The efuse array as claimed in claim 3, wherein the first transistors are N-type MOS transistors, and the second transistor is an N-type MOS transistor.

8. An efuse device comprising:
a plurality of first lines;
at least one second line, where the first lines are interlaced with the second line;
a plurality of cells disposed in an array, each corresponding to one set of the interlaced first line and second line, wherein each cell has first and second terminals respectively coupled to the corresponding interlaced first line and second line;
a plurality of first selection devices, each coupled to one of the first lines;
at least one second selection device, coupled to the second line; and
a plurality of sensing circuits, each coupled to the second line and one of the first lines, wherein the states of the cells coupled to the same first line are sensed by the same sensing circuit.

9. The efuse device as claimed in claim 8, wherein in a writing mode, when at least one first selection device and the second selection device are turned on, at least one cell, which corresponds to the interlaced first and second lines of the turned-on first and second selection devices, is selected.

10. The efuse device as claimed in claim 8, wherein each first selection device comprises a first transistor having a control terminal receiving a first writing signal, a first terminal coupled to a source line, and a second terminal coupled to the corresponding first line, and the second selection device comprises a second transistor having a control terminal receiving a second writing signal, a first terminal coupled to a ground voltage, and a second terminal coupled to the second line.

11. The efuse device as claimed in claim 10, wherein in a writing mode, when at least one first transistor and the second transistor are turned on respectively by the first and second writing signals, at least one cell, which corresponds to the interlaced first and second lines of the turned-on first and second transistors, is selected.

12. The efuse device as claimed in claim 10, wherein each of the cells comprises a fuse, and the source line provides a current for blowing the fuses.

13. The efuse device as claimed in claim 10, wherein the first transistors are P-type MOS transistors, and the second transistor is an N-type MOS transistor.

14. The efuse device as claimed in claim 10, wherein the first transistors are N-type MOS transistors, and the second transistor is an N-type MOS transistor.

15. The efuse device as claimed in claim 8, wherein the first lines are word lines, and the second line is a bit line.

16. The efuse device as claimed in claim 8, wherein each of the sensing circuits comprises:
a reference resistor having a first terminal coupled to the corresponding first line and a second terminal;
an isolation unit coupled between the second terminal of the reference resistor and the second line, wherein the isolation unit is turned off in a writing mode and on in a reading mode;
a pre-charging unit having first and second input nodes coupled to the isolation unit, wherein the pre-charging unit charges voltages at the first and second nodes to a predetermined level before the isolation unit is turned on, and the first and second input nodes respectively receive a first voltage of the second terminal of the reference resistor and a second voltage on the second line of the sensed cell when the isolation unit is turned on;
an amplifying unit coupled to the first and second input nodes of the pre-charging unit and amplifying the first and second voltages; and
an output unit receiving the amplified first and second voltages and outputting an output signal according to the amplified first and second voltages.

17. The efuse device as claimed in claim 16, wherein each of the cells comprises a fuse, and whether the fuse is blown or not is determined according to the corresponding output signal.

18. The efuse device as claimed in claim 16 further comprising reading transistors respectively coupled between the cells and a reference voltage and turned on in the reading mode.

19. The efuse device as claimed in claim 16, wherein in each of the sensing circuits, a ratio of the first voltage to the second voltage is proportional to a ratio of impedance of the reference resistor to the sensed cell.

20. An efuse blowing method for an efuse array, wherein the efuse array comprises a plurality of word lines, at least one bit line interlaced with the word lines, a plurality of first selection devices respectively coupled to the word lines, and at least one second selection device coupled to the bit line, comprising:
determining a first cell among the cells to be blown, wherein the first cell corresponds to a first set of the interlaced word line and bit line;
turning on the first selection device coupled to the word line of the first set;
turning on the second selection device coupled to the bit line of the first set; and
providing a current through the word line of the first set to the first cell for blowing.
